(19) United States
(12) Patent Application Publication
(10) Pub. No.: US 2025/0149851 A1
(43) Pub. Date: May 8, 2025

(54) LASER MODULE

(71) Applicant: Lextar Electronics Corporation, Hsinchu City (TW)

(72) Inventors: Yi-Min CHEN, Hsinchu City (TW); Kai-Hung CHENG, Hsinchu City (TW); Ming-Jing LEE, Hsinchu City (TW); Jung-Tang CHU, Hsinchu City (TW)

(21) Appl. No.: 18/935,144

(22) Filed: Nov. 1, 2024

(30) Foreign Application Priority Data
Nov. 2, 2023 (TW) 112142206

(51) Int. Cl. H01S 5/02255; H01S 5/02208

(52) U.S. Cl. CPC H01S 5/02255; H01S 5/02208

(57) ABSTRACT

A laser module is provided. The laser module includes a substrate, a laser diode and a diffuser. The substrate has a surface and a base plane, wherein the base plane is parallel to the surface. The laser diode is disposed on the surface. The diffuser is disposed above the laser diode, wherein an included angle is formed between the diffuser and the base plane, and the included angle is greater than 5 degrees.

### CROSS REFERENCE TO RELATED DISCLOSURES

This application claims priority of Taiwan Patent Application No. 112142206, filed on Nov. 2, 2023, the entirety of which is incorporated by reference herein.

### Technical Field

The present disclosure relates to a laser module, and, in particular, to a laser module providing the light-shape off-axis effect.

### BACKGROUND

### Description of the Related Art

The light-emitting principles of light-emitting diodes (LEDs), as well as their and structure, are different from those of traditional light sources. Light-emitting diodes (LEDs) have the advantages of low power consumption, long component life, no warm-up time, and fast response speeds. In addition, light-emitting diodes (LEDs) have small sizes and improved vibration-resistance, which makes them suitable for mass production. Moreover, they can be easily made into extremely small or array-type components to meet a variety of application requirements. Light-emitting diodes (LEDs) are widely utilized in various consumer electronics products available on the market, such as optical display devices, laser diodes, traffic signals, data storage devices, communication devices, lighting devices, and medical devices, among others.

Conventionally, laser modules are utilized in scenarios such as pedestrian identification for autonomous vehicles and walking-path identification for sweeping robots. In order to concentrate the light beam provided by a laser module on the necessary area (for example, in the application of walking path-recognition of a sweeping robot, the light beam is concentrated on the ground), the laser module must be installed in an inclined manner. The conventional design increases the cost of the design and the size of the finished product.

### SUMMARY

An embodiment of the present disclosure provides a laser module. The laser module includes a substrate, a laser diode and a diffuser. The substrate has a surface and a base plane, wherein the base plane is parallel to the surface. The laser diode is disposed on the surface. The diffuser is disposed above the laser diode, wherein an included angle is formed between the diffuser and the base plane, and the included angle is greater than 5 degrees.

Utilizing the laser module according to the embodiment of the present disclosure, the laser module can provide a light-shape off-axis effect, and the light beam provided by the laser module can be directly concentrated on the necessary area (for example, in the disclosure of walking-path recognition of a sweeping robot, the light beam is concentrated on the ground). The laser module is prevented from being installed in an inclined manner. The laser module of the disclosed embodiment can be easily installed. The costs of design and parts are decreased, and the overall size of the finished product is reduced.

The laser module of the embodiment of the present disclosure can be used in products such as pedestrian recognition for autonomous vehicle driving, vehicle reversing radar, gesture recognition, walking-path recognition for sweeping robots or unmanned guided vehicles. The disclosure does not mean to restrict the present disclosure. The laser module of the disclosed embodiment can also be utilized in other products.

### BRIEF DESCRIPTION OF THE DRAWINGS

The present disclosure can be more fully understood by reading the subsequent detailed description and examples with references made to the accompanying drawings, wherein:

FIG. 1 is a perspective view of the laser module of the embodiment of the present disclosure;

FIG. 2 is a cross-sectional view of the laser module of a first embodiment of the present disclosure;

FIG. 3 shows the light emission situation of the laser module according to the embodiment of the present disclosure; and

FIG. 4 is a cross-sectional view of a laser module of a second embodiment of the present disclosure

### DETAILED DESCRIPTION

The following description is made for the purpose of illustrating the general principles of the present disclosure and should not be taken in a limiting sense. The scope of the present disclosure is best determined by reference to the appended claims.

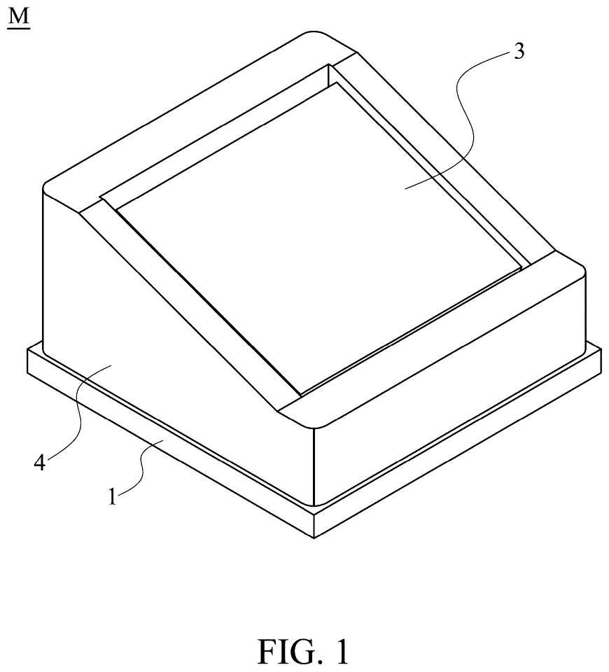

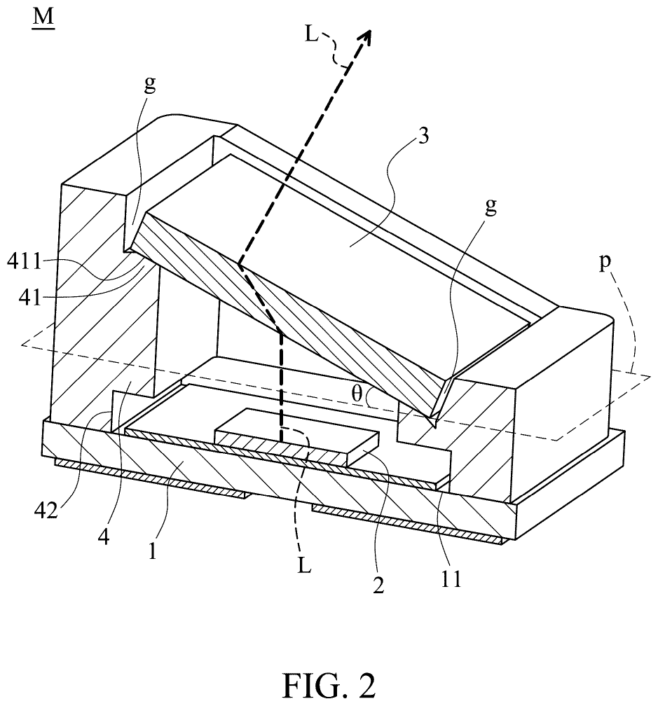

FIG. 1 is a perspective view of the laser module of the embodiment of the present disclosure. FIG. 2 is a cross-sectional view of the laser module of a first embodiment of the present disclosure. With reference to FIGS. 1 and 2, in one embodiment, the laser module M of the embodiment of the present disclosure includes a substrate 1, a laser diode 2 and a diffuser 3. The substrate 1 has a surface 11 and a base plane P. The base plane P is parallel to the surface 11. The laser diode 2 is disposed on the surface 11. The laser diode 2 provides a light beam L. The diffuser 3 is disposed above the laser diode 2. An included angle θ is formed between the diffuser 3 and the base plane P. The included angle θ is greater than 5 degrees.

With reference to FIG. 2, in one embodiment, the included angle is lower than 70 degrees. For example, in one embodiment, the included angle θ can be 20 degrees, 35 degrees or 50 degrees.

With reference to FIG. 2, in one embodiment, the laser module M further includes a reflector 4. The reflector 4 is disposed on the substrate 1 and surrounding the laser diode 2. The diffuser 3 is disposed on the reflector 4 and is supported by the reflector 4.

In one embodiment, the substrate 1 and the reflector 4 can be integrally formed. The disclosure is not meant to restrict the present disclosure.

With reference to FIG. 2, in one embodiment, the medium between the laser diode 2 and the diffuser 3 is air. The disclosure is not meant to restrict the present disclosure. In another embodiment, gases of other types can be filled between the laser diode 2 and the diffuser 3.

With reference to FIG. 2, in one embodiment, the material of the reflector 4 is selected from Liquid-Crystal Polymer, ceramic and copper. In another embodiment, an inner surface of the reflector 4 can be coated with a reflective layer.

With reference to FIG. 2, in one embodiment, the reflector 7 comprises a supporting portion 41 and an inner surface 42. The supporting portion 41 is formed on the inner surface 42. The diffuser 3 is supported by the supporting portion 41. In the embodiment of the present disclosure, the supporting portion 41 has an inclined surface 411 relative to the base plane P. The inclined surface 411 is adapted to contact the diffuser 3. In another embodiment, the supporting portion 41 supports four corners of the diffuser 3. The disclosure is not meant to restrict the present disclosure.

With reference to FIG. 2, in one embodiment, the reflector 4 is rectangular, circular, or cup-shaped. A gap g is formed between the diffuser 3 and the inner surface 42. In one embodiment, the gap g can be filled by glue. In another embodiment of the present disclosure, the diffuser 3 can be attached to the reflector 4 by glue.

With reference to FIG. 2, in one embodiment, the material of the substrate 1 is selected from ceramic, glass fiber (FR4), resin (BT) and solid molding materials (EMC).

Referencing to FIG. 2, in one embodiment, the material of the diffuser 3 is selected from polymer and glass.

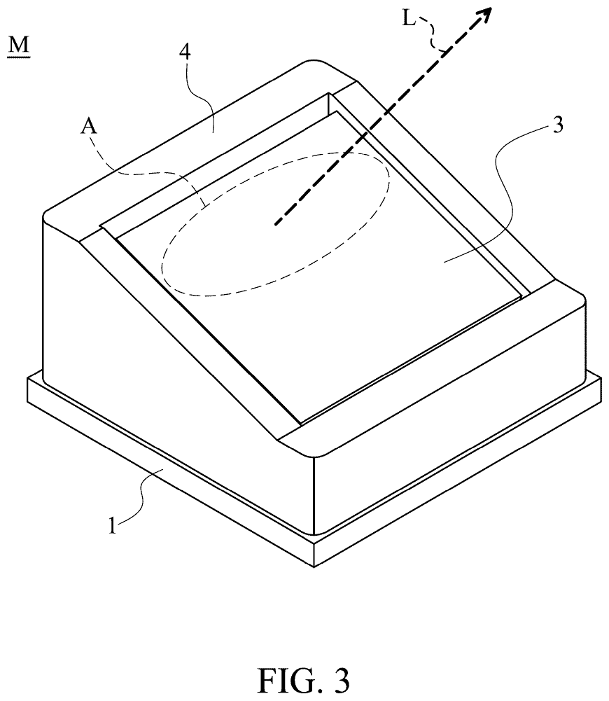

FIG. 3 shows the light emission situation of the laser module according to the embodiment of the present disclosure. With reference to FIG. 3, utilizing the laser module of the disclosed embodiment, in one embodiment, the laser diode is a surface light source. The light emission range of the light beam L is mainly concentrated in the necessary area A on the diffuser 3. The light-shape becomes, for example, a light-shape off-axis of (+19/−41 degrees, +38/−45 degrees). Therefore, the light beam L can be concentrated to the required part, and the induction intensity is increased and energy loss in unnecessary areas is decreased. The above light-shape off-axis data are only examples and are not meant to restrict the present disclosure.

Referencing to FIGS. 2 and 3, in an embodiment of the present disclosure, the light emission angle of the above-mentioned light-shape off-axis light beam L can be perpendicular to the diffuser 3. However, the foregoing disclosure does not mean to restrict the present disclosure. According to actual needs, the light emission angle of the light beam L can be appropriately adjusted.

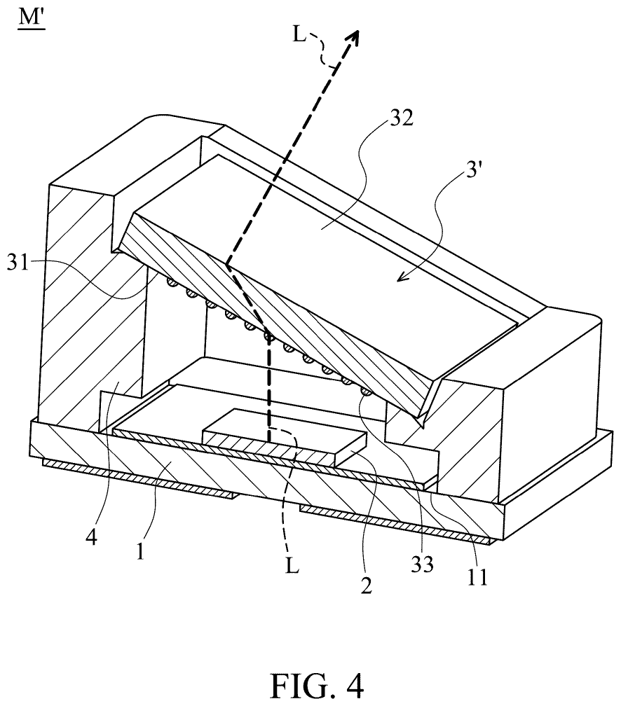

FIG. 4 is a cross-sectional view of a laser module of a second embodiment of the present disclosure. With reference to FIG. 4, in this embodiment, the laser module M′ includes a substrate 1, a laser diode 2 and a diffuser 3′. The laser diode 2 is disposed on the substrate 1. The laser diode 2 provides a light beam L. The diffuser 3′ is disposed above the laser diode 2. The laser module M′ further includes a reflector 4. The reflector 4 is disposed on the substrate 1 and surrounding the laser diode 2. The diffuser 3′ is disposed on the reflector 4 and is supported by the reflector 4. In this embodiment, the diffuser 3′ comprises a bias microstructure 33, a light-entering surface 31 and a light-emitting surface 32. The bias microstructure 33 is formed on the light-entering surface 31. The light beam L enters the diffuser 3′ via the light-entering surface 31, and leaves the diffuser 3′ via the light-emitting surface 32. The bias microstructure 33 provides more significant light-shape off-axis effect. In one embodiment, the bias microstructure 33 is a bias microstructure for diffusion.

With reference to FIG. 4, in one embodiment, the medium between the laser diode 2 and the diffuser 3′ is air. The disclosure is not meant to restrict the present disclosure. In another embodiment, gases of other types can be filled between the laser diode 2 and the diffuser 3′. In one embodiment, the material of the reflector 4 is selected from Liquid-Crystal Polymer, ceramic and copper. In another embodiment, an inner surface of the reflector 4 can be coated with a reflective layer. In another embodiment of the present disclosure, the diffuser 3′ can be attached to the reflector 4 by glue. The material of the substrate 1 is selected from ceramic, glass fiber (FR4), resin (BT) and solid molding materials (EMC). The material of the diffuser 3′ is selected from polymer and glass.

Utilizing the laser module according to the embodiment of the present disclosure, the laser module can provide a light-shape off-axis effect, and the light beam provided by the laser module can be directly concentrated on the necessary area (for example, in the disclosure of walking-path recognition of a sweeping robot, the light beam is concentrated on the ground). The laser module is prevented from being installed in an inclined manner. The laser module of the disclosed embodiment can be easily installed. The costs of design and parts are decreased, and the overall size of the finished product is reduced.

The laser module of the embodiment of the present disclosure can be used in products such as pedestrian recognition for autonomous vehicle driving, vehicle reversing radar, gesture recognition, walking-path recognition for sweeping robots or unmanned guided vehicles. The disclosure does not meet to restrict the present disclosure. The laser module of the disclosed embodiment can also be utilized in other products.

While the present disclosure has been described by way of example and in terms of the preferred embodiments, it should be understood that the present disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A laser module, comprising:
a substrate, having a surface and a base plane, wherein the base plane is parallel to the surface;
a laser diode, disposed on the surface; and
a diffuser, disposed above the laser diode, wherein an included angle is formed between the diffuser and the base plane, and the included angle is greater than 5 degrees.

2. The laser module as claimed in claim 1, wherein the included angle is lower than 70 degrees.

3. The laser module as claimed in claim 1, wherein the laser diode provides a light beam.

4. The laser module as claimed in claim 3, wherein the diffuser comprises a bias bias microstructure, a light-entering surface and a light-emitting surface, the bias microstructurebias bias microstructure is formed on the light-entering surface, and the light beam enters the diffuser via the light-entering surface, and leaves the diffuser via the light-emitting surface.

5. The laser module as claimed in claim 1, further comprising a reflector, wherein the reflector is disposed on the substrate and surrounding the laser diode, and the diffuser is disposed on the reflector and is supported by the reflector.

6. The laser module as claimed in claim 5, wherein the material of the reflector is selected from a group consisting of Liquid-Crystal Polymer, ceramic and copper.

7. The laser module as claimed in claim 5, wherein the reflector comprises a supporting portion and an inner surface, the supporting portion is formed on the inner surface, and the diffuser is supported by the supporting portion.

8. The laser module as claimed in claim 5, wherein the reflector is rectangular, circular, or cup-shaped.

9. The laser module as claimed in claim 1, wherein the material of the substrate is selected from a group consisting of ceramic, glass fiber (FR4), resin (BT) and solid molding materials (EMC).

10. The laser module as claimed in claim 1, wherein the material of the diffuser is selected from a group consisting of polymer and glass.
